(19) United States
(12) Patent Application Publication
(10) Pub. No.: US 2014/0339489 A1
(43) Pub. Date: Nov. 20, 2014

(54) PHASE-CHANGE MEMORY DEVICE AND METHOD FOR MANUFACTURING THE SAME

(71) Applicant: Intellectual Discovery Co., Ltd., Seoul (KR)

(72) Inventor: Deok Kee KIM, Seoul (KR)

(73) Assignee: Intellectual Discovery Co., Ltd., Seoul (KR)

(21) Appl. No.: 14/218,473

(22) Filed: Mar. 18, 2014

(30) Foreign Application Priority Data
Mar. 22, 2013 (KR) 10-2013-0030926

(51) Int. Cl. H01L 45/00

(52) U.S. Cl. CPC H01L 45/1246; H01L 45/06; H01L 45/16; H01L 45/143; H01L 45/144
USPC 257/2; 438/382

(57) ABSTRACT

A phase-change memory device is provided. The memory device includes a lower electrode, a phase-change material layer formed on the lower electrode, an upper electrode formed on the phase-change material layer, and a stress insulation film formed to surround the phase-change material layer.

### CROSS-REFERENCE TO RELATED APPLICATION

This application claims priority from and the benefit of Korean Patent Application No. 10-2013-0030926 filed on Mar. 22, 2013, which is incorporated herein by reference for all purposes as if fully set forth herein.

### BACKGROUND

1. Field

The embodiments described herein pertain generally to a phase-change memory device and a method for manufacturing the same.

2. Discussion of the Background

A phase-change memory device (PRAM) exhibits the most superior characteristics and is currently the closest to large production among many next-generation memory devices. Further, the phase-change memory device has been rated as one of ultimate memory devices in that thanks to the relatively simple device structure and manufacturing process of the phase-change memory device, compared to other memory devices, the phase-change memory device can be applied to both stand-alone memories and embedded memories for SoC.

In the phase-change memory device, writing operation of the memory is called “reset” and relates to a process of turning the phase of the phase-change material into a amorphous state. The phase-change material can be transformed into the amorphous state by heating the phase-change material to a melting point or higher using Joule heat produced by an electric pulse, and then, rapidly quenching the material.

In the phase-change memory device, removing operation of the memory is called “set” and relates to a process of turning the phase of the phase-change material into a crystalline state. The phase-change material can be transformed into the crystalline state by heating the phase-change material to a melting point or higher using Joule heat produced by an electric pulse, and then, holding the material for a certain time or longer.

However, for commercialization of the phase-change memory device, the problem of deterioration in reliability of the phase-change memory device resulting from change in the composition of the phase-change material layer needs to be resolved.

Main cause of the change is as follows. The writing and erasing operations of the phase-change memory device accompany high heat and currents as described above. Therefore, atoms composing the phase-change material get to move due to thermal dispersion, or electromigration resulting from collision with electrons at a high temperature, so that the change in the composition of the phase-change material layer occurs.

Thus, in order to increase the reliability of the phase-change memory device, the movement of the atoms composing the phase-change material should be suppressed so that the initial composition of the phase-change material layer is maintained.

In this regard, Korean Patent Application Publication No. 10-2010-0097715 (Title of Invention: Phase-Change Memory Device with Improved Writing/Removing Durability Characteristic and Programming Method Thereof) describes a phase-change memory device, which increases its reliability by returning movement of atoms composing a phase-change material to the initial state through reverse restoring pulse having a direction opposite to writing current pulse and removing current pulse of the phase-change memory device.

### SUMMARY

In view of the foregoing, example embodiments provide a phase-change memory device, which has high reliability by suppressing movement of atoms in the phase-change material.

In accordance with an example embodiment, a phase-change memory device is provided. The memory device includes a lower electrode, a phase-change material layer formed on the lower electrode, an upper electrode formed on the phase-change material layer, and a stress insulation film formed to surround the phase-change material layer.

In accordance with the embodiment, upon programming, the stress insulation film may apply stress to the phase-change material layer so as to suppress movement of atoms in the phase-change material layer.

In accordance with another example embodiment, a method for manufacturing a phase-change memory device is provided. The method includes forming a lower electrode, forming a phase-change material layer on the lower electrode, forming an upper electrode on the phase-change material layer, and forming a stress insulation film to surround the phase-change material layer.

In accordance with the embodiment, in the forming the stress insulation film, upon programming, the stress insulation film may apply stress to the phase-change material layer so as to suppress movement of atoms in the phase-change material layer.

In accordance with the example embodiments, it is possible to provide a highly-reliable phase-change memory device, which includes a stress insulation film formed on a phase-change material layer, and thereby, suppressing movement of atoms in the phase-change material layer so as to prevent change in the composition of the phase-change material layer.

### BRIEF DESCRIPTION OF THE DRAWINGS

FIG. 1 is a conceptual view showing a direction (A) of movement of atoms composing a phase-change material layer and a direction (B) of stress applied by a stress insulation film upon programming, in a phase-change memory device in accordance with an example embodiment;

FIG. 2 to FIG. 4 are cross-sectional views of phase-change memory devices provided with stress insulation films in different forms in accordance with various example embodiments;

FIG. 5 is a flow chart showing a method for manufacturing a phase-change memory device in accordance with an example embodiment;

FIG. 6A to FIG. 6D schematically show a manufacturing process of a phase-change memory device in accordance with an example embodiment as shown in FIG. 2;

FIG. 7 schematically shows a manufacturing process, which is additionally carried out after FIG. 6D to manufacture a phase-change memory device in accordance with an example embodiment as shown in FIG. 3; and

FIG. 8A and FIG. 8B schematically show a manufacturing process of the phase-change memory device in accordance with an example embodiment as shown in FIG. 4.

### DETAILED DESCRIPTION OF THE ILLUSTRATED EMBODIMENTS

Hereinafter, example embodiments will be described in detail with reference to the accompanying drawings so that inventive concept may be readily implemented by those skilled in the art. However, it is to be noted that the present disclosure is not limited to the example embodiments but can be realized in various other ways. In the drawings, certain parts not directly relevant to the description are omitted to enhance the clarity of the drawings, and like reference numerals denote like parts throughout the whole document.

Throughout the whole document, the term “on” that is used to designate a position of one element with respect to another element includes both a case that the one element is adjacent to the another element and a case that any other element exists between these two elements.

Throughout the whole document, the term “comprises or includes” and/or “comprising or including” used in the document means that one or more other components, steps, operations, and/or the existence or addition of elements are not excluded in addition to the described components, steps, operations and/or elements. Throughout the whole document, the terms “about or approximately” or “substantially” are intended to have meanings close to numerical values or ranges specified with an allowable error and intended to prevent accurate or absolute numerical values disclosed for understanding of the present invention from being illegally or unfairly used by any unconscionable third party. Through the whole document, the term “step of” does not mean “step for.”

Throughout the whole document, the term “combination of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

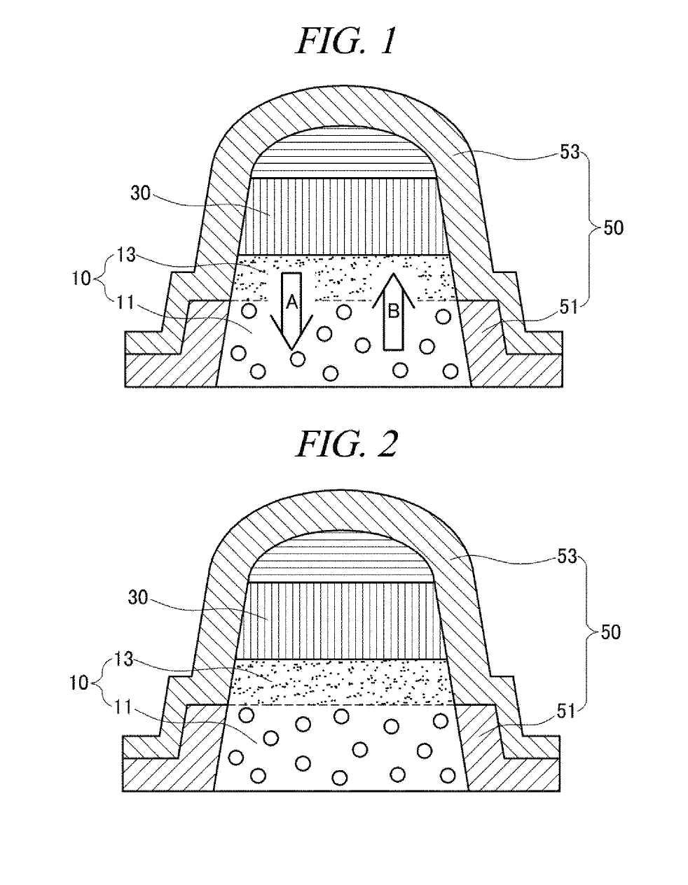

For reference, in the descriptions of the example embodiments, terms related to directions or positions (upper side, lower side and others) have been defined based on the position state of each component shown in the drawings. For example, in FIG. 1, the upper portion may be the upper side, and the lower portion may be the lower side. However, in actually applying various example embodiments, the components may be positioned in various directions, e.g., the upper and lower sides may be reversed.

Hereinafter, the example embodiments are described in detail with reference to the accompanying drawings.

FIG. 1 is a conceptual view showing a direction (A) of movement of atoms composing a phase-change material layer and a direction (B) of stress applied to a stress insulation film upon programming, in a phase-change memory device in accordance with an example embodiment. FIG. 2 to FIG. 4 are cross-sectional views of phase-change memory devices provided with stress insulation films in different forms in accordance with various example embodiments.

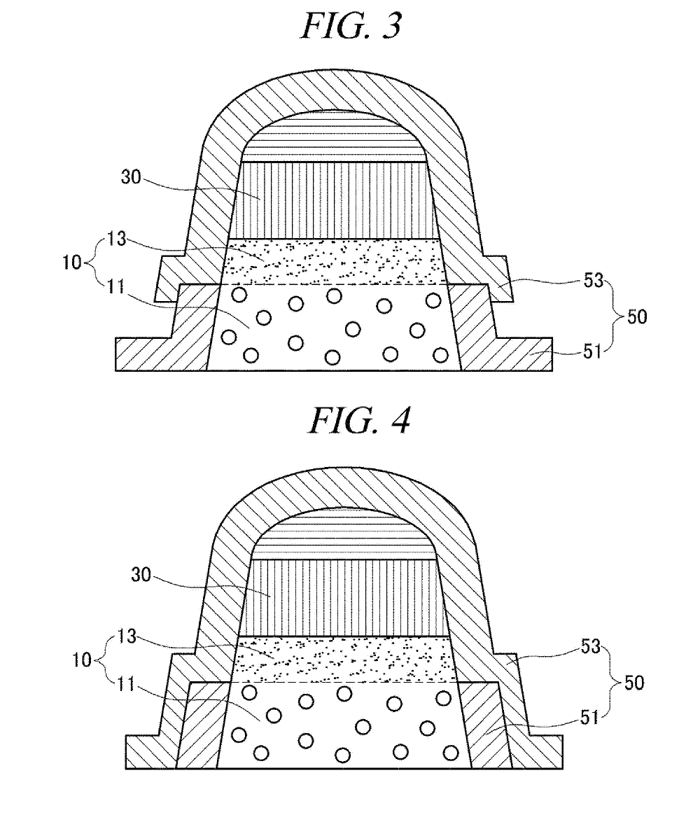

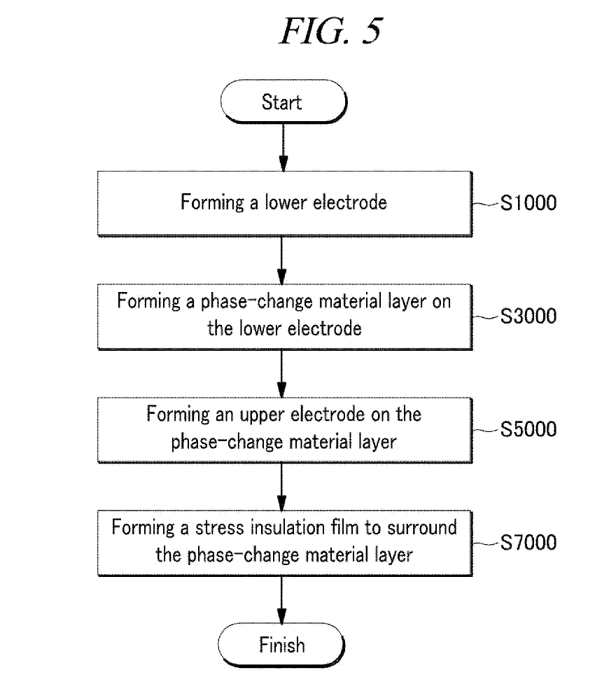

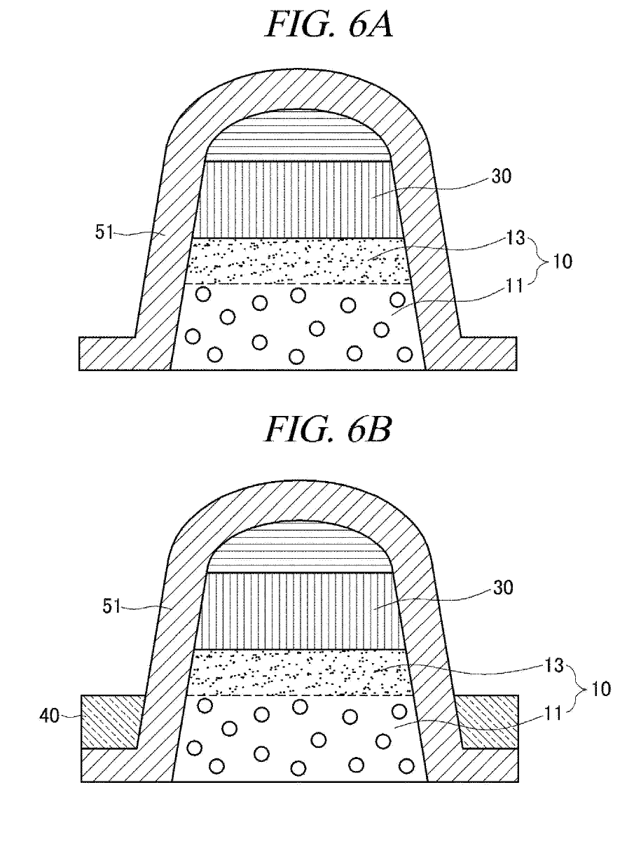

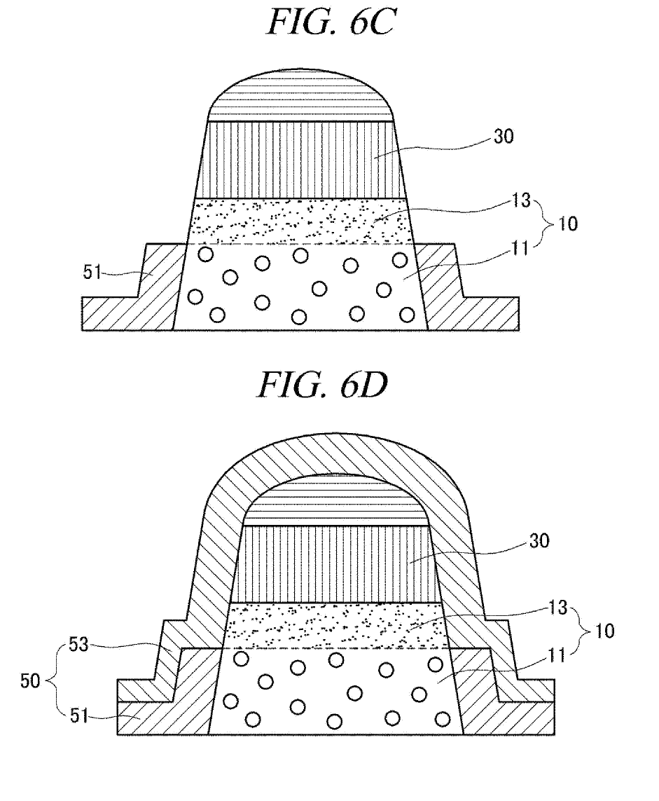

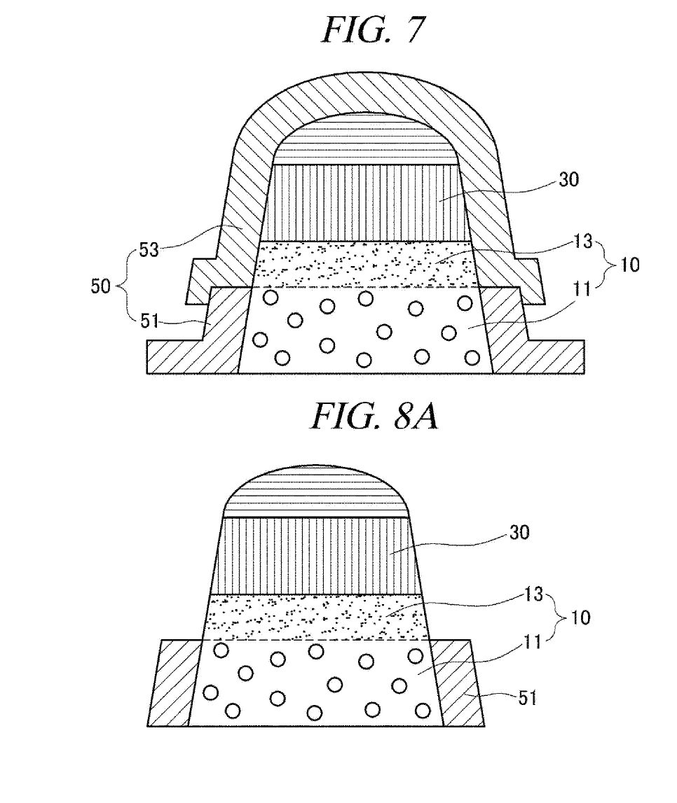

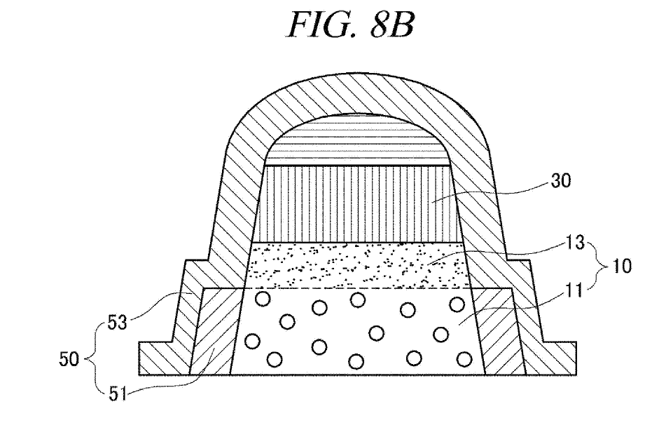

In addition, FIG. 5 is a flow chart showing a method for manufacturing a phase-change memory device in accordance with an example embodiment. FIG. 6A to FIG. 6D schematically show a manufacturing process of the phase-change memory device illustrated in FIG. 2. FIG. 7 schematically shows a manufacturing process, which is additionally carried out after FIG. 6D to manufacture the phase-change memory device illustrated in FIG. 3. FIG. 8A to FIG. 8B schematically show a manufacturing process of the phase-change memory device illustrated in FIG. 4.

First, the phase-change memory device in accordance with an example embodiment of the present disclosure (hereinafter, the “present disclosure of a phase-change memory device”) is described.

The present disclosure of a phase-change memory device includes a lower electrode (not illustrated).

The lower electrode may act as a heater electrode that turns a phase-change material layer into an amorphous or crystalline state as described later.

The lower electrode may include platinum (Pt), ruthenium (Ru), iridium (Ir), silver (Ag), aluminum (Al), titanium (Ti), tantalum (Ta), tungsten (W), silicon (Si), copper (Cu), nickel (Ni), cobalt (Co), molybdenum (Mo), conductive nitrides thereof (e.g., TiN and MoN), conductive oxynitrides thereof (e.g., TiON), or combinations thereof (e.g., TiSiN and TiAlON). However, these materials are merely illustrative and are not limited thereto.

The present disclosure of a phase-change memory device includes a phase-change material layer 10.

The phase-change material layer 10 may undergo reversible phase changes between the amorphous state and the crystalline state depending on the temperature and/or the duration of the heat applied.

In general, the phase-change material layer 10 has high resistance in the amorphous state and low resistance in the crystalline state. By using such bi-stable resistive states of the phase-change material layer 10, logical information of “0” or “1” can be allocated, and in this way, information can be stored in the phase-change memory device.

The phase-change material layer 10 may include a chalcogenide-based compound. The chalcogenide-based compound may include, for example, a GeSbTe-based material, i.e., any one of GeSb₂Te₃, Ge₂Sb₂Te₅, GeSb₂Te₄ or combinations thereof.

In addition, in another example embodiment, the phase-change material layer 10 may include any one of GeTeAs, GeSnTe, GeSeTe, GeTeSnAu, SeSb₂, InSe, GeTe, BiSeSb, PdTeGeSn, InSeTiCo, InSbTe, In₃SbTe₂, GeTeSb₂, GeTeSb, GeSbTePd, and AgInSbTe or combinations thereof.

In addition, the phase-change material layer 10 may include materials, in which the above-described materials are further doped with impurity elements, e.g., non-metal elements such as B, C, N and P.

The phase-change material layer 10 is formed on the lower electrode.

The crystalline phases of the phase-change material layer 10 may be changed by the lower electrode acting as a heater electrode in contact with the phase-change material layer 10.

That is, when a voltage for program of the memory is applied to between the upper electrode 30 and the lower electrode, the phase-change material layer 10 may undergo a phase change due to the Joule heat generated on the contact interface between the lower electrode and the phase-change material layer 10.

The phase-change material layer 10 may include a first area 11, in which due to movement of the atoms composing the phase-change material layer 10, the atoms are accumulated so as to generate compressive stress.

In addition, the phase-change material layer 10 may include a second area 13, in which due to the movement of atoms composing the phase-change material layer 10, the atoms are depleted so as to generate tensile stress.

When the voltage for programs is applied, and thus, phase change of the phase-change material layer 10 occurs, in the phase-change material layer 10, parts of the atoms composing the phase-change material layer 10 may move toward the direction of the lower electrode, and the other atoms may move toward the direction of the upper electrode 30 due to electromigration and thermal dispersion effects. If the amount of the atoms moving toward one of the directions is larger than the amount of the atoms moving toward the other direction, the movement of atoms can be regarded as going in one direction after all. For example, with reference to FIG. 1, if the amount of the atoms moving toward the direction A is larger than the amount of the atoms moving toward the direction B, it can be regarded as the movement of atoms is in the direction A.

When such phase changes of the phase-change material layer 10 repeatedly occur through repeated writing and operating process of the memory device, the movement of the atoms toward the direction A continuously occurs within the phase-change material layer 10, and therefore, the first area 11 may be formed, where the atoms are accumulated and build up the compressive stress.

On the other hand, the repeated occurring of the movement of the atoms toward the direction A may also form the second area 13, where the tensile stress is built up due to the depletion of atoms.

The first area 11 may be positioned closer to the lower electrode than to the upper electrode 30. On the other hand, the second area 13 may be positioned closer to the upper electrode 30 than to the lower electrode.

If the amount of the atoms moving toward the lower electrode is larger than the amount of the atoms moving toward the upper electrode 30, atoms may be eventually accumulated in the area of the phase-change material layer 10 closer to the lower electrode, whereas atoms may be depleted in the area of the phase-change material layer 10 closer to the upper electrode 30.

In other words, as illustrated in FIG. 1, as atoms composing the phase-change material layer 10 move toward the direction A more, the first area 11, in which atoms are accumulated, may be formed to be closer to the lower electrode, and the second area 13, in which atoms are depleted, may be formed to be closer to the upper electrode 30.

For example, if the phase-change material layer 10 includes a chalcogenide-based compound, Ge atoms and Sb atoms may move toward the direction of the lower electrode, and Te atoms may move toward the direction of the upper electrode 30.

The present disclosure of a phase-change memory device includes the upper electrode 30.

The upper electrode 30 may include platinum (Pt), ruthenium (Ru), iridium (Ir), silver (Ag), aluminum (Al), titanium (Ti), tantalum (Ta), tungsten (W), silicon (Si), copper (Cu), nickel (Ni), cobalt (Co), molybdenum (Mo), conductive nitrides thereof (e.g., TiN and MoN), conductive oxynitrides thereof (e.g., TiON), or combinations thereof (e.g., TiSiN and TiAlON). However, these materials are merely illustrative and are not limited thereto.

The upper electrode 30 is formed on the phase-change material layer 10.

The present disclosure of a phase-change memory device includes a stress insulation film 50.

The stress insulation film 50 is formed to surround the phase-change material layer 10.

As illustrated in FIG. 1 to FIG. 4, the stress insulation film 50 may be formed to surround an outer circumference of the phase-change material layer 10.

The stress insulation film 50 may apply stress to the phase-change material layer 10, upon programming, to suppress the movement of the atoms composing the phase-change material layer 10.

As described above, the atoms composing the phase-change material layer 10 move due to thermal dispersion and electromigration of the atoms upon repeated memory writing and erasing operations, and as a result, the composition of the phase-change material layer 10 can become different from the initial composition.

In order to improve the reliability of the phase-change memory device, the phase-change material layer 10 should maintain its initial composition. To this end, the movement of the atoms of the phase-change material layer 10 should be suppressed.

With reference to FIG. 1, the present disclosure of a phase-change memory device can suppress the movement of the atoms composing the phase-change material layer 10, by applying stress through the stress insulation film 50 in the opposite direction B to the direction of the movement A of the atoms. Accordingly, the initial composition of the phase-change material layer 10 can be maintained in spite of repeated programs, so that the reliability of the phase-change memory device can be improved.

The stress insulation film 50 may include a compressive stress insulation film 51 that applies compressive stress to the first area 11.

Also, the stress insulation film 50 may include a tensile stress insulation film 53 that applies tensile stress to the second area 13.

With reference to FIG. 1, due to a difference between the compressive stress applied to the first area 11 by the compressive stress insulation film 51 and the tensile stress applied to the second area 13 by the tensile stress insulation film 53, a force (force in the direction B) directed from the first area 11 toward the second area 13 may be applied to the atoms positioned at a boundary of the first area 11 and the second area 13, as illustrated in FIG. 1. Accordingly, the movement of the atoms toward the direction A is suppressed, and the change in the composition of the phase-change material layer 10 is prevented, so that the reliability of the phase-change memory device can be improved.

The difference in the stress characteristics between the compressive stress insulation film 51 and the tensile stress insulation film 53 may be generated by adjusting and controlling compositions of the thin films, conditions of the manufacturing process thereof, and others.

For example, the compressive stress insulation film 51 may be a tensile nitride film, and the tensile stress insulation film 53 may be a compressive nitride film.

With reference to FIG. 1 to FIG. 4, the compressive stress insulation film 51 may be formed on the circumference of the first area 11. Accordingly, the compressive stress insulation film 51 can apply compressive stress to the first area 11.

The compressive stress insulation film 51 may be formed in a “ [symbol] ” shape as illustrated in FIG. 2 and FIG. 3.

Or, the compressive stress insulation film 51 may be formed in a column shape contacting only with the outer circumference of the phase-change material layer 10 as illustrated in FIG. 4.

With reference to FIG. 1 to FIG. 4, the tensile stress insulation film 53 may be formed on the circumference of the second area 13. Accordingly, the tensile stress insulation film 53 can apply tensile stress to the second area 13.

A lower portion of the tensile stress insulation film 53 may be formed on the outer circumference of the compressive stress insulation film 51.

The lower portion of the tensile stress insulation film 53 may be formed to surround the outer circumference of the compressive stress insulation film 51 in various forms.

For example, the tensile stress insulation film 53 may be formed to surround the whole outer circumference of the compressive stress insulation film 51 as illustrated in FIG. 2 and FIG. 4. In this case, processes become simplified, compared to forming the stress insulation film 50 in the shape illustrated in FIG. 3, because it is sufficient to simply deposit the tensile stress insulation film 53 on the whole compressive stress insulation film 51, and a separate process after the deposition of the tensile stress insulation film 53 is unnecessary.

Or, the tensile stress insulation film 53 may be formed to surround only part of the outer circumference of the compressive stress insulation film 51. In this case, since the influence of the stress by the tensile stress insulation film 53 on the compressive stress insulation film 51 can be minimized, the difference between the stress applied to the second area 13 by the tensile stress insulation film 53 and the stress applied to the first area 11 by the compressive stress insulation film 51 is increased, so that the effect in suppressing the movement of the atoms within the phase-change material layer 10 can be maximized.

In order to form the tensile stress insulation film 53 in the shape illustrated in FIG. 3, a method that forms the tensile stress insulation film 53 in the shape illustrated in FIG. 2, and then, etches the lower portion of the tensile stress insulation film 53 through anisotropic etching may be used.

In addition, the upper portion of the tensile stress insulation film 53 may be formed on the circumference of the upper electrode 30.

With reference to FIG. 1 to FIG. 4, the tensile stress insulation film 53 may be formed to surround even the upper electrode 30 together with the phase-change material layer 10.

In this case, since a process for removing part of the tensile stress insulation film 53 or others after depositing the tensile stress insulation film 53 as a whole is unnecessary, processes are simplified.

Meanwhile, the stress insulation film 50 may include at least one of a nitride film and an oxide film.

A nitride film or an oxide film is generally used for integration of a memory device. By controlling only a deposition condition and others while using the conventional nitride or oxide film process, it is possible to form the compressive stress insulation film 51 and the tensile stress insulation film 53. Accordingly, it is possible to effectively form the stress insulation film 50 without requiring any additional process.

However, considering that films having different compositions can also realize the difference in the stress characteristics between the compressive stress insulation film 51 and the tensile stress insulation film 53, it will be understood that materials for the stress insulation film 50 are not limited to aforementioned thin films including at least one of a nitride film and an oxide film.

Now, the method for manufacturing a phase-change memory device in accordance with an example embodiment of the present disclosure (hereinafter, the “present disclosure of a phase-change memory device manufacturing method”) will be described. Components, which are identical or similar to those of the phase-change memory device in accordance with the example embodiment that has been described, will be denoted by the same reference numerals as used for the components of the phase-change memory device. In addition, overlapping descriptions with those for the phase-change memory device will be omitted.

FIG. 5 is a flow chart showing a method for manufacturing a phase-change memory device in accordance with an example embodiment.

The present disclosure of a phase-change memory device manufacturing method includes forming a lower electrode (S1000).

The lower electrode may be formed on a substrate (not illustrated), on which a switching device for selection of unit memory cells and a wiring structure are formed, to be electrically connected to the switching device and the wiring structure.

The present disclosure of a phase-change memory device manufacturing method includes forming the phase-change material layer 10 on the lower electrode (S3000).

The phase-change material layer 10 may be deposited on the lower electrode through a deposition process showing a superior single-layer deposition or coating performance such as chemical vapor deposition (CVD) or atom layer deposition.

As described above, the phase-change material layer 10 may undergo reversible phase changes between the amorphous state and the crystalline state depending on the temperature of heat to be applied and/or the heating time.

For example, the phase-change material layer 10 may include a chalcogenide-based compound. The chalcogenide-based compound may include, for example, a GeSbTe-based material, i.e., any one of GeSb₂Te₃, Ge₂Sb₂Te₅, GeSb₂Te₄ or combinations thereof.

In forming the phase-change material layer 10 (S3000), the phase-change material layer 10 may form the first area 11, in which due to movement of atoms composing the phase-change material layer 10, atoms are accumulated so as to generate compressive stress.

In forming the phase-change material layer 10 (S3000), the phase-change material layer 10 may form the second area 13, in which due to movement of atoms composing the phase-change material layer 10, atoms are depleted so as to generate tensile stress.

As described above, when the phase change of the phase-change material layer 10 repeatedly occurs through repeated writing and operating of the memory device, the first area 11, in which atoms are accumulated so as to build up the compressive stress, may be formed within the phase-change material layer 10.

On the other hand, the second area 13, in which the tensile stress is built up, may be formed in the area of the phase-change material layer 10, in which atoms are depleted.

In forming the phase-change material layer 10 (S3000), the first area 11 may be formed to be positioned closer to the lower electrode than to the upper electrode 30.

In forming the phase-change material layer 10 (S3000), the second area 13 may be formed to be positioned closer to the upper electrode 30 than to the lower electrode.

As described above, where atoms composing the phase-change material layer 10 move more toward the direction A (the direction toward the lower electrode), the first area 11, in which atoms are accumulated, may be formed to be closer to the lower electrode, and the second area 13, in which atoms are depleted, may be formed to be closer to the upper electrode 30.

The present disclosure of a phase-change memory device manufacturing method includes forming the upper electrode 30 on the phase-change material layer (S5000).

The present disclosure of a phase-change memory device manufacturing method includes forming the stress insulation film 50 to surround the phase-change material layer (S7000).

In forming the stress insulation film 50 (S7000), the stress insulation film 50 may be formed to apply stress acting to suppress the movement of the atoms composing the phase-change material layer 10 to the phase-change material layer 10, upon programming.

As described above, with reference to FIG. 1, the present disclosure of a phase-change memory device can suppress the movement of the atoms composing the phase-change material layer 10, by applying stress in the direction (B) opposite to the direction (A) of the movement of the atoms through the stress insulation film 50. In this way, the initial composition of the phase-change material layer 10 can be maintained even upon the repeated programming, so that the reliability of the phase-change memory device can be improved.

The step (S7000) of forming the stress insulation film 50 may include forming the compressive stress insulation film 51, which applies compressive stress to the first area 11.

The step (S7000) of forming the stress insulation film 50 may include forming the tensile stress insulation film 53, which applies tensile stress to the second area 13.

The compressive stress insulation film 51 and the tensile stress insulation film 53 may be formed by adjusting compositions of thin films, conditions for the manufacturing process, and others, and thereby, generating the difference in the stress characteristics.

For example, the compressive stress insulation film 51 may be a tensile nitride film, and the tensile stress insulation film 53 may be a compressive nitride film.

In forming the compressive stress insulation film 51, the compressive stress insulation film 51 may be formed on the circumference of the first area 11.

The compressive stress insulation film 51 and the tensile stress insulation film 53 may be formed in various forms as illustrated in from FIG. 2 to FIG. 4.

For example, the compressive stress insulation film 51 may be formed in a “L” shape as illustrated in FIG. 2 and FIG. 3, or n a column shape as illustrated in FIG. 4.

Detailed descriptions of the method for forming the compressive stress insulation film 51 in the shapes illustrated in from FIG. 2 to FIG. 4 will be provided later.

In forming the tensile stress insulation film 53, the tensile stress insulation film 53 may be formed on the circumference of the second area 13.

In this case, the lower portion of the tensile stress insulation film 53 may be formed on the outer circumference of the compressive stress insulation film 51. In addition, the upper portion of the tensile stress insulation film 53 may be formed on the circumference of the upper electrode 30.

As described above, the tensile stress insulation film 53 may be formed in a shape that surrounds the whole outer side of the compressive stress insulation film 51 as illustrated in FIG. 2 and FIG. 4. In this case, since it is sufficient to deposit the tensile stress insulation film 53 on the whole compressive stress insulation film 51, processes are easy, compared to FIG. 3.

More specifically, with reference to FIG. 6D and FIG. 8B, in order to form the tensile stress insulation film 53 in the shapes illustrated in FIG. 2 and FIG. 4, it is sufficient to simply deposit the tensile stress insulation film 53 on the compressive stress insulation film 51, and extra processes such as removing part of the tensile stress insulation film 53 as shown in FIG. 3 are unnecessary.

Additionally, the tensile stress insulation firm 53 may be formed in the shape that surrounds only part of the outer circumference of the compressive stress insulation film 51 as illustrated in FIG. 3. In this case, since the influence of the stress by the tensile stress insulation film 53 on the compressive stress insulation film 51 can be minimized, the difference between the stress applied to the second area 13 by the tensile stress insulation film 53 and the stress applied to the first area 11 by the compressive stress insulation film 51 is increased so that the effect in suppressing the movement of the atoms within the phase-change material layer 10 can be maximized.

In order to form the tensile stress insulation film 53 in the shape illustrated in FIG. 3, a process for removing the lower portion of the tensile stress insulation film 53 as shown in FIG. 7, e.g., anisotropic etching may be used after FIG. 6D.

Detailed descriptions of the method for forming the tensile stress insulation film 53 in the shapes illustrated in from FIG. 2 to FIG. 4 will be provided later.

In forming the stress insulation film 50 (S7000), the stress insulation film 50 may be formed including at least one of a nitride film and an oxide film.

In this case, as described above, the stress insulation film 50 may be formed by adjusting compositions and various conditions of processes and others used when forming a nitride film or an oxide film useful for integration of a conventional phase-change memory device, and thereby, generating the difference in the stress characteristics. Accordingly, the stress insulation film 50 can be effectively formed without requiring an additional process.

As described above, there are various examples for the phase-change memory device, in which the compressive stress insulation film 51 is formed on the circumference of the first area 11, and the tensile stress insulation film 53 is formed on the circumference of the second area 13. Those examples include the embodiments illustrated in FIG. 2 through FIG. 4. Hereinafter, more specific methods for manufacturing the phase-change memory device in accordance with various example embodiments are described.

FIG. 6A to FIG. 6D show a manufacturing process for depicting an example for a manufacturing method of the phase-change memory device illustrated in FIG. 2 in accordance with an example embodiment.

With reference to FIG. 6A, forming the compressive stress insulation film 51 may include depositing the compressive stress insulation film 51 on the circumference of the phase-change material layer 10 and the upper electrode 30.

For example, the compressive stress insulation film 51 may be deposited through physical vapor deposition (PVD) such as sputtering and vaporization deposition or chemical vapor deposition (CVD) such as plasma enhanced chemical vapor deposition and atmospheric chemical vapor deposition, in which compositions, conditions, and others are controlled such that the compressive stress insulation film 51 has the stress characteristic that applies compressive stress.

Thereafter, forming the compressive stress insulation film 51 may include etching part of the compressive stress insulation film 51 to expose the second area 13 and the upper electrode 30.

With reference to FIG. 6B, a photo-resist layer 40 may be formed on the circumference of the compressive stress insulation film 51 formed on the circumference of the first area 11. Thereafter, the exposed compressive stress insulation film 51 may be etched, such that the second area 13 can be exposed as illustrated in FIG. 6C.

With reference to FIG. 6D, forming the tensile stress insulation film 53 may include depositing the tensile stress insulation film 53 on the circumference of the second area 13 and the circumference of the upper electrode 30.

For example, the tensile stress insulation film 53 may be deposited through physical vapor deposition (PVD) such as sputtering and vaporization deposition or chemical vapor deposition (CVD) such as plasma enhanced chemical vapor deposition and atmospheric chemical vapor deposition, in which compositions, conditions, and others are controlled such that the tensile stress insulation film 53 has the stress characteristic that applies tensile stress.

As described above, since the method for forming the stress insulation film 50 in the shape illustrated in FIG. 2 does not require an additional process after the deposition of the tensile stress insulation film 53 in the shape illustrated in FIG. 6D, processes are simple, compared to the method for forming the stress insulation film 50 in the shape illustrated in FIG. 3. Accordingly, costs for the manufacturing process can be reduced.

FIG. 7 shows a manufacturing process, which is additionally carried out after FIG. 6D to manufacture an example for the phase-change memory device illustrated in FIG. 3.

Forming the tensile stress insulation film 53 may include removing the lower portion of the tensile stress insulation film 53 to expose the lower portion of the compressive stress insulation film 51, after the deposition of the tensile stress insulation film 53.

With reference to FIG. 7, by removing part of the lower portion of the tensile stress insulation film 53 formed through the process of FIG. 6D, the tensile stress insulation film 53 only above the dotted line in FIG. 7 may remain. In this case, the lower portion of the tensile stress insulation film 53 may be removed through anisotropic etching.

As described above, in case of forming the stress insulation film 50 in the shape illustrated in FIG. 3, the difference between the stress applied to the second area 13 by the tensile stress insulation film 53 and the stress applied to the first area 11 by the compressive stress insulation film 51 is increased, so that the effect in suppressing the movement of the atoms within the phase-change material layer 10 can be maximized.

FIG. 8A and FIG. 8B show a manufacturing process for depicting the method for manufacturing the phase-change memory device illustrated in FIG. 4.

With reference to FIG. 8A, forming the compressive stress insulation film 51 may include depositing the compressive stress insulation film 51 on the circumference of the first area 11 according to a spacer forming process.

The spacer forming process may include a process for forming a film through photolithography, an etching process, and others. Through the spacer forming process, the compressive stress insulation film 51 may be formed in a column shape as illustrated in FIG. 8A.

For example, the compressive stress insulation film 51 may be deposited through physical vapor deposition (PVD) such as sputtering and vaporization deposition or chemical vapor deposition (CVD) such as plasma enhanced chemical vapor deposition and atmospheric chemical vapor deposition, in which compositions, conditions, and others are controlled such that the compressive stress insulation film 51 has the stress characteristic that applies compressive stress.

With reference to FIG. 8B, forming the tensile stress insulation film 53 may include forming the tensile stress insulation film 53 on the circumference of the second area 13 and the circumference of the upper electrode 30.

For example, the tensile stress insulation film 53 may be deposited through physical vapor deposition (PVD) such as sputtering and vaporization deposition or chemical vapor deposition (CVD) such as plasma enhanced chemical vapor deposition and atmospheric chemical vapor deposition, in which compositions, conditions, and others are controlled such that the tensile stress insulation film 53 has the stress characteristic that applies tensile stress.

Since the method for forming the stress insulation film 50 in the shape illustrated in FIG. 4 does not require an additional process after the deposition of the tensile stress insulation film 53, processes are simple, compared to the method for forming the stress insulation film 50 in the shape illustrated in FIG. 3. Accordingly, costs for the manufacturing process can be reduced.

The present disclosure can improve the reliability such as endurance of PRAM products, by applying stress to the phase-change material layer 10 in a direction opposite to the direction of the movement of the atoms composing the phase-change material layer 10 through the stress insulation film 50, and thereby, preventing the change in the composition of the phase-change material layer 10 caused from the movement of the atoms by thermal dispersion and electromicgration during repeated memory writing and erasing processes. Accordingly, the commercialization of the phase-change memory devices will be able to be realized earlier.

Furthermore, since the present disclosure can produce the stress insulation film 50 through the process for forming a nitride film or an oxide film usually used for integration of the phase-change memory device, they do not require an additional process and can be easily realized by controlling deposition conditions of the process for forming a nitride or oxide film, which are being currently used.

The above description of the example embodiments is provided for the purpose of illustration, and it would be understood by those skilled in the art that various changes and modifications may be made without changing technical conception and essential features of the example embodiments. Thus, it is clear that the above-described example embodiments are illustrative in all aspects and do not limit the present disclosure. For example, each component described to be of a single type can be implemented in a distributed manner. Likewise, components described to be distributed can be implemented in a combined manner.

The scope of the inventive concept is defined by the following claims and their equivalents rather than by the detailed description of the example embodiments. It shall be understood that all modifications and embodiments conceived from the meaning and scope of the claims and their equivalents are included in the scope of the inventive concept.

1. A phase-change memory device, comprising:
a lower electrode;
a phase-change material layer formed on the lower electrode;
an upper electrode formed on the phase-change material layer; and
a stress insulation film formed to surround the phase-change material layer.

2. The phase-change memory device of claim 1,
wherein, upon programming, the stress insulation film applies stress to the phase-change material layer so as to suppress movement of atoms in the phase-change material layer.

3. The phase-change memory device of claim 2,
Wherein, due to the movement of the atoms, the phase-change material layer comprises a first area, in which the atoms are accumulated so as to generate compressive stress, and a second area, in which the atoms are depleted so as to generate tensile stress, and
the stress insulation film comprises a compressive stress insulation film that applies compressive stress to the first area, and a tensile stress insulation film that applies tensile stress to the second area.

4. The phase-change memory device of claim 3,
wherein the first area is positioned closer to the lower electrode than to the upper electrode, and the second area is positioned closer to the upper electrode than to the lower electrode.

5. The phase-change memory device of claim 4,
wherein the compressive stress insulation film is formed on a circumference of the first area, and
the tensile stress insulation film is formed on a circumference of the second area.

6. The phase-change memory device of claim 5,
wherein a lower portion of the tensile stress insulation film is formed on an outer circumference of the compressive stress insulation film, and an upper portion of the tensile stress insulation film is formed on a circumference of the upper electrode.

7. The phase-change memory device of claim 1,
wherein the stress insulation film includes at least one of a nitride film and an oxide film.

8. A method for manufacturing a phase-change memory device comprising:
forming a lower electrode;
forming a phase-change material layer on the lower electrode;
forming an upper electrode on the phase-change material layer; and
forming a stress insulation film to surround the phase-change material layer.

9. The method for manufacturing a phase-change memory device of claim 8,
wherein, in the forming the stress insulation film,
upon programming, the stress insulation film is formed to apply stress to the phase-change material layer so as to compress movement of atoms in the phase-change material layer.

10. The method for manufacturing a phase-change memory device of claim 9,
wherein, in the forming the phase-change material layer,
due to the movement of the atoms, the phase-change material layer is formed to include a first area, in which the atoms are accumulated so as to generate compressive stress, and a second area, in which the atoms are depleted so as to generate tensile stress, and
the forming of the stress insulation film comprises:
forming a compressive stress insulation film that applies compressive stress to the first area; and
forming a tensile stress insulation film that applies tensile stress to the second area.

11. The method for manufacturing a phase-change memory device of claim 10,
wherein, in the forming the phase-change material layer,
the phase-change material layer is formed so as for the first area to be positioned closer to the lower electrode than to the upper electrode, and the second area to be positioned closer to the upper electrode than to the lower electrode.

12. The method for manufacturing a phase-change memory device of claim 11,
wherein, in the forming the compressive stress insulation film,
the compressive stress insulation film is formed on a circumference of the first area, and
in the forming the tensile stress insulation film,
the tensile stress insulation film is formed on a circumference of the second area.

13. The method for manufacturing a phase-change memory device of claim 12,
wherein, in the forming the tensile stress insulation film,
a lower portion of the tensile stress insulation film is formed on an outer circumference of the compressive stress insulation film, and an upper portion of the tensile stress insulation film is formed on a circumference of the upper electrode.

14. The method for manufacturing a phase-change memory device of claim 13,
wherein the forming of the compressive stress insulation film comprises:
depositing the compressive stress insulation film on the circumference of the phase-change material layer and the upper electrode; and
etching part of the compressive stress insulation film to expose the second area and the upper electrode, and
the forming of the tensile stress insulation film comprises:
depositing the tensile stress insulation film on the circumference of the second area, the circumference of the upper electrode, and the outer circumference of the compressive stress insulation film.

15. The method for manufacturing a phase-change memory device of claim 14,
wherein the forming of the tensile stress insulation film comprises removing a lower portion of the tensile stress insulation film, after the deposition of the tensile stress insulation film, to expose the lower portion of the compressive stress insulation film.

16. The method for manufacturing a phase-change memory device of claim 13,
wherein the forming of the compressive stress insulation film comprises depositing the compressive stress insulation film on the circumference of the first area according to a spacer forming process, and
the forming of the tensile stress insulation film comprises depositing the tensile stress insulation film on the circumference of the second area, the circumference of the upper electrode, and the outer circumference of the compressive stress insulation film.

17. The method for manufacturing a phase-change memory device of claim 8,
wherein, in the forming the stress insulation film,
the stress insulation film includes at least one of a nitride film and an oxide film.
